(19) United States
(12) Patent Application Publication
(10) Pub. No.: US 2016/0276287 A1
(43) Pub. Date: Sep. 22, 2016

(54) SEMICONDUCTOR DEVICE

(71) Applicant: RENESAS ELECTRONICS CORPORATION, Kanagawa (JP)

(72) Inventor: Masaru IWABUCHI, Kanagawa (JP)

(73) Assignee: RENESAS ELECTRONICS CORPORATION, Kanagawa (JP)

(21) Appl. No.: 14/381,482

(22) PCT Filed: Dec. 6, 2013
(86) PCT No.: PCT/JP2013/082793

§ 371 Date: Aug. 27, 2014

(51) Int. Cl. H01L 23/552; H01L 23/522; H01L 27/112; H01L 23/528

(52) U.S. Cl. CPC H01L 23/552; H01L 23/5286; H01L 23/5223; H01L 27/11286

(57) ABSTRACT

A semiconductor device capable of achieving a reduction of noise is provided. For example, the semiconductor device includes a first region for forming a core circuit block CRBK, a power-source voltage line LNVD1 disposed in the first region, a power-source voltage line LNVD2 disposed on the outside of the first region, and an on-chip capacitor CC. The CC has an upper electrode UPN being a partial section of the LNVD2, and a lower electrode LWN to which a reference power source voltage VSS is supplied. The CC is configured by a unit cell. An internal power source voltage VDD from a power-source source node is supplied to a CRBK through the UPN.

### TECHNICAL FIELD

The present invention relates to a semiconductor device, and for example relates to a technique which is effectively applied to a semiconductor device such as a microcomputer.

### BACKGROUND

For example, Patent Document 1 discloses a technique of reducing power source noises by using a decoupling capacitor which is configured such that a power-source potential line and a ground potential line are disposed in the vicinity of each unit cell and an insulating film is disposed between the power-source potential line and the ground potential line. In addition, Patent Document 2 discloses a configuration in which an outer peripheral power source line connected to a power-source terminal pad and an inner-circuit power source line (for the power source potential and the ground potential) provided between an inner circuit and an outer peripheral power source line are provided, and the outer peripheral power source line and the inner-circuit power source line are connected only at one place. The inner-circuit power source line (for the power source potential) and the power source line (for the ground potential) are disposed adjacent to each other for forming an RC filter, so that EMI noises generated by the inner circuit are attenuated.

### PRIOR ART DOCUMENTS

### Patent Documents

### Patent Document 1: Japanese Patent Application Laid-Open Publication No. 2008-300765

### Patent Document 2: Japanese Patent Application Laid-Open Publication No. 2009-283792

### SUMMARY

### Problems to be Solved by the Invention

In recent years, semiconductor devices represented by a microcomputer and the like are increased in speed and decreased in an internal power source voltage as the process has been scaled down, so that countermeasures against power source noises and electromagnetic compatibility (EMC) noises gradually rise in importance. Accordingly, for example, using the technologies of Patent Document 1 and Patent Document 2 are conceivable.

The technology of Patent Document 1 is a technology in which, in the internal circuit (core circuit) inside the semiconductor device, a power supply noise is reduced in a power supply potential line and a ground potential line, which are present in the internal circuit. However, a necessary capacitance value may not be sufficiently secured by only an inter-line capacitance in such an internal circuit. Also, on the power supply line until arriving at the internal circuit from a power supply terminal, it is apprehended that a power supply noise generated by IR drop or the like cannot be sufficiently reduced.

The technology of Patent Document 2 is a technology in which all sections of the power supply line connecting the power supply terminal and the internal circuit (core circuit) functions as an RC filter. However, in order to sufficiently secure the characteristic of the RC filter, a long power supply line may be needed between the power supply terminal and the internal circuit. In this case, an EMI noise (emission noise) from the internal circuit to the power supply terminal can be reduced, but, conversely, IR drop easily occurs in the power source voltage supplied from the power supply terminal to the internal circuit. Therefore, the internal circuit may malfunction due to the power supply noise.

The embodiments described hereinafter are made in consideration of the foregoing. The above and other preferred aims and novel characteristics of the present invention will be apparent from the description of the present specification and the accompanying drawings.

### Means for Solving the Problems

A semiconductor device according to an embodiment is configured in a single semiconductor substrate and includes a first region, a first power-source voltage line, a power-source source node, a second power-source voltage line, and an on-chip capacitor. The first region is a region provided to form a core circuit block performing a predetermined process. The first power-source voltage line is disposed in the first region to supply a power source voltage to the core circuit block. The power-source source node is disposed on the outside of the first region to serve as a supply source of the power source voltage. The second power-source voltage line is disposed to connect the power-source source node and the first power-source voltage line. The on-chip capacitor has a first electrode being a partial section of the second power-source voltage line, and a second electrode to which a reference power source voltage is supplied. The on-chip capacitor is configured by a unit cell. The power source voltage from the power-source source node is supplied to the core circuit block through the first electrode.

### Effects of the Invention

According to an embodiment, a reduction of noise can be achieved.

### BRIEF DESCRIPTION OF THE DRAWINGS

FIG. 1 is a plan view illustrating a schematic overall configuration example of a semiconductor device according to a first embodiment of the present invention;

FIG. 2 is a plan view illustrating a schematic configuration example different from FIG. 1;

FIG. 3A is a plan view illustrating a schematic configuration example of a wiring board on which the semiconductor device of FIG. 1 is mounted;

FIG. 3B is a plan view illustrating a schematic configuration example of a wiring board on which the semiconductor device of FIG. 2 is mounted;

FIG. 4 is a circuit diagram illustrating an example of an equivalent circuit including a power regulator circuit and a surrounding in the semiconductor device of FIG. 1;

FIG. 5 is a circuit block diagram illustrating an actual configuration example of a surrounding of the power regulator circuit in the semiconductor device of FIG. 1;

FIG. 6 is a schematic diagram illustrating a schematic configuration example of a main part in the semiconductor device of FIG. 1;

FIG. 7 is a schematic diagram illustrating a schematic configuration example of a main part in the semiconductor device of FIG. 2;

FIG. 8A is a circuit symbol schematically illustrating an on-chip capacitor in FIGS. 6 and 7;

FIG. 8B is a circuit symbol of comparative example of FIG. 8A;

FIG. 9 is a plan view illustrating a schematic arrangement example of the on-chip capacitors in the semiconductor devices of FIGS. 6 and 7;

FIG. 10 is a schematic diagram illustrating various configuration examples of the on-chip capacitors in the semiconductor devices of FIGS. 6 and 7;

FIG. 11A is a plan view illustrating a schematic arrangement example of an on-chip capacitor inside a semiconductor chip in a semiconductor device according to a second embodiment of the present invention;

FIG. 11B is a plan view illustrating a detailed layout configuration example of a partial region in FIG. 11A;

FIG. 12A is a cross-sectional view illustrating a configuration example between A-A′ in FIG. 11B, and FIG. 12B is a cross-sectional view illustrating a configuration example between B-B′ in FIG. 11B;

FIG. 13A is a diagram illustrating a cross-sectional configuration simply showing FIG. 12A and an example of an equivalent circuit thereof;

FIG. 13B is a diagram illustrating a cross-sectional configuration of comparative example of FIG. 13A and an example of an equivalent circuit thereof;

FIG. 14 is a cross-sectional view illustrating a configuration example of a metal gate used as a gate line in the on-chip capacitors of FIGS. 12A and 12B;

FIG. 15A is a plan view illustrating a schematic arrangement example of an on-chip capacitor and a power regulator circuit inside a semiconductor chip in a semiconductor device according to a third embodiment of the present invention;

FIG. 15B is a plan view illustrating a detailed layout configuration example of a partial region in FIG. 15A;

FIG. 16A is a plan view illustrating a schematic arrangement example of an on-chip capacitor inside a semiconductor chip in a semiconductor device according to the third embodiment of the present invention;

FIG. 16B is a plan view illustrating a detailed layout configuration example of a partial region of FIG. 16A;

FIG. 17A is a plan view illustrating a detailed layout configuration example of each on-chip capacitor in FIG. 16B;

FIG. 17B is a cross-sectional view illustrating a configuration example between C-C′ in FIG. 17A;

FIG. 18 is a three-dimensional view schematically illustrating a configuration example of a part in the on-chip capacitors of FIGS. 17A and 17B; and

FIGS. 19A to 19D are schematic diagrams illustrating different configuration examples of a main part in a semiconductor device according to a fifth embodiment of the present invention.

### DETAILED DESCRIPTION

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof. Also, in the embodiments described below, when referring to the number of elements (including number of pieces, values, amount, range, and the like), the number of the elements is not limited to a specific number unless otherwise stated or except the case where the number is apparently limited to a specific number in principle. The number larger or smaller than the specified number is also applicable.

Further, in the embodiments described below, it goes without saying that the components (including element steps) are not always indispensable unless otherwise stated or except the case where the components are apparently indispensable in principle. Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

Moreover, while the circuit elements forming respective function blocks of embodiments are not particularly limited, by integrated circuit technology for known CMOS (complimentary MOS transistor) etc., they are formed on a semiconductor substrate of, for example, single crystal silicon. Hereinafter, embodiments of the present invention will be described in detail with reference to the accompanying drawings. Note that components having the same function are denoted by the same reference symbols throughout the drawings for describing the embodiment, and the repetitive description thereof will be omitted.

### First Embodiment

### Schematic Configuration of Entire Semiconductor Device

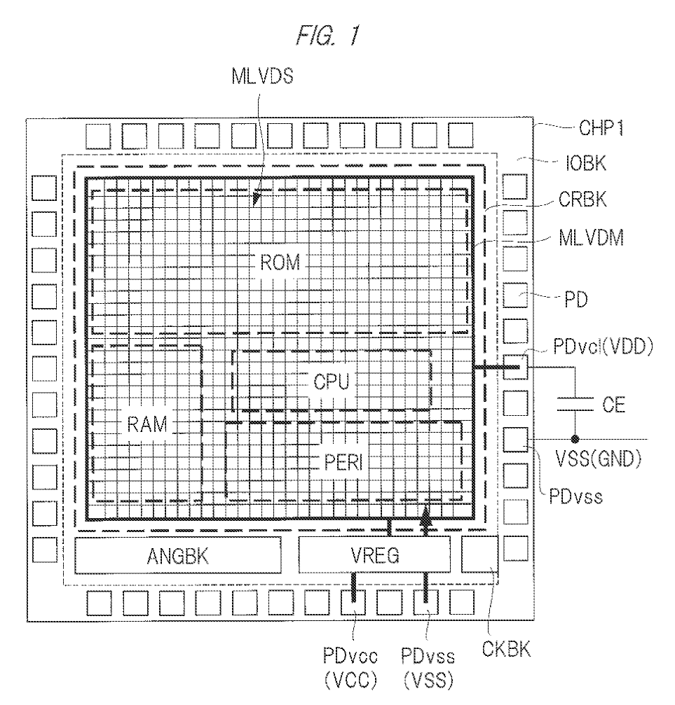

FIG. 1 is a plan view schematically illustrating an exemplary configuration of an entire semiconductor device according to the first embodiment of the invention. As an example of the semiconductor device, FIG. 1 illustrates a semiconductor chip CHP1 which includes one semiconductor substrate. Examples of the CHP1 include a microcomputer and the like. The CHP1 includes an external input/output block (IO block) IOBK in an outer peripheral portion, and includes therein a core circuit block CRBK, an analog circuit block ANGBK, a power-source voltage regulator circuit VREG, and a clock generating circuit block CKBK. In the IOBK, a plurality of pads PD are disposed. In the PDs, a pad PDvcc for a power source voltage VCC, a pad PDvss for a reference power source voltage VSS (a ground power source voltage GND), and a pad PDvcl for an internal power source voltage VDD are included.

Examples of the analog circuit block ANGBK include various types of analog circuits representing an analog-to-digital conversion circuit and a digital-to-analog conversion circuit. Although not illustrated, for example, the ANGBK is directly supplied with power from the pad PD. The power-source voltage regulator circuit VREG receives the power source voltage VCC from the pad PDvcc and the reference power source voltage VSS from the pad PDvss, and generates the internal power source voltage VDD. The VCC is such as 2.7 V to 5.5 V, and the VDD is such as 1.1 V to 1.8 V, but not limited thereto. The clock generating circuit block CKBK, for example, includes a crystal oscillation circuit, a phase locked loop (PLL) circuit and the like, and generates various types of clock signals which are used in the semiconductor chip CHP.

The core circuit block CRBK is a circuit block which executes a predetermined process according to the internal power source voltage VDD supplied from the power-source voltage regulator circuit VREG, and to which a miniaturization process is applied. The CRBK includes a nonvolatile memory ROM such as a flash memory, a volatile memory RAM such as a static random access memory (SRAM), a processor circuit CPU, and various types of peripheral circuits PERI such as a timer circuit and a serial communication circuit. Further, the CRBK includes a main power-source voltage line MLVDM which is disposed along the outer peripheral portion and a sub power-source voltage line MLVDS which is disposed in a mesh shape branched from the MLVDM. The MLVDS is generally formed using lines thinner than those of the MLVDM.

The main power-source voltage line MLVDM is connected to the output of the power-source voltage regulator circuit VREG, and the internal power-source voltage VDD is supplied thereto. The respective circuits in the CRBK are appropriately connected to the MLVDS, and supplies the VDD through the MLVDM and the MLVDS from the VREG. Further, the MLVDM is connected to the pad PDvcl for the internal power source voltage VDD. The PDvcl is a pad serving to stabilize the VDD, and an external capacitor CE to be provided on the outside of the semiconductor chip CHP1 is connected between the PDvcl and the pad PDvss for the reference power source voltage VSS. The CE, such as, is a laminated ceramic capacitor having a capacitance value in a range of 0.1 μF to 1 μF. In addition, although not illustrated, similarly to the power-source voltage lines (MLVDM and MLVDS) for the VDD, the CHP1 practically includes a reference power-source voltage line for the VSS including a main reference power-source voltage line and a sub reference power-source voltage line. The main reference power-source voltage line is connected to the PDvss.

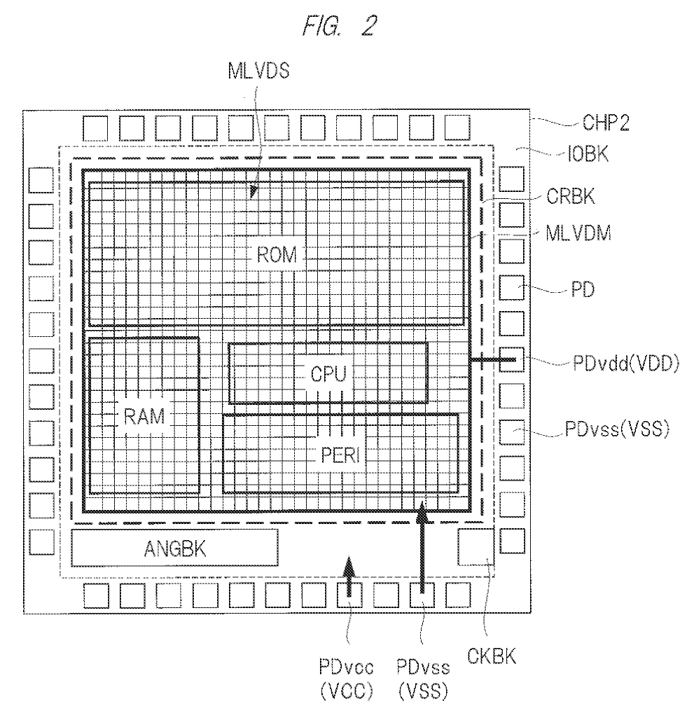

FIG. 2 is a plan view illustrating a schematic configuration example different from FIG. 1. A semiconductor chip CHP2 illustrated in FIG. 2 differs from the semiconductor chip CHP1 of FIG. 1 in that the semiconductor chip CHP2 includes no power regulator circuit VREG. Therefore, in the CHP2 of FIG. 2, the pad PDvcl for the stabilization of the internal power source voltage VDD in FIG. 1 is changed to a pad PDvdd for supply of VDD. VDD, which is generated on the outside of the CHP2, is supplied to the PDvdd.

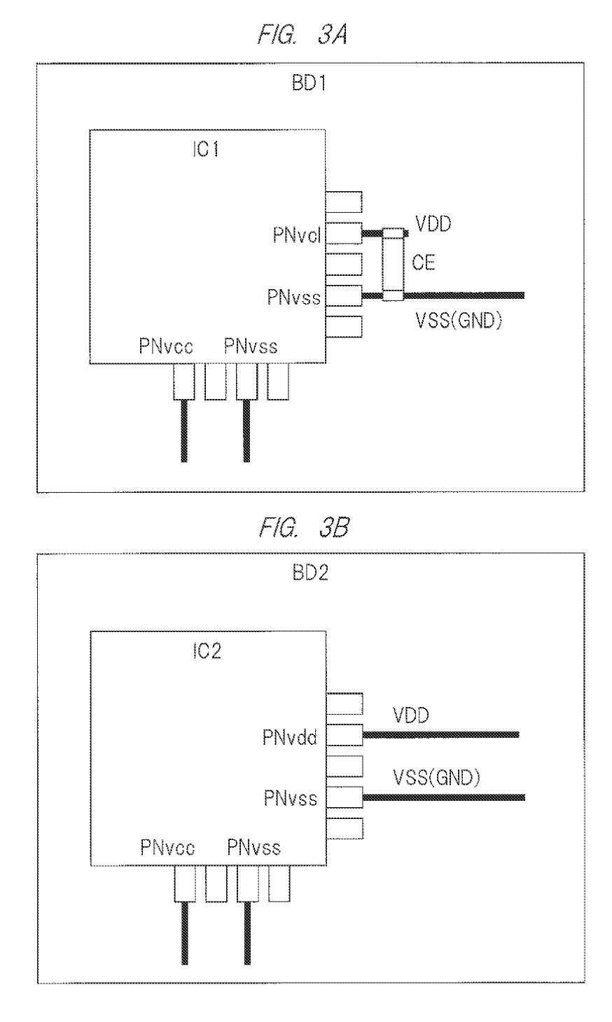

FIG. 3A is a plan view illustrating a schematic configuration example of a wiring board on which the semiconductor device of FIG. 1 is mounted, and FIG. 3B is a plan view illustrating a schematic configuration example of a wiring substrate on which the semiconductor device of FIG. 2 is mounted. On the wiring board BD1 illustrated in FIG. 3A, a semiconductor package IC1 is mounted as an example of the semiconductor device. The IC1 is provided by packaging the semiconductor chip CHP1 of FIG. 1. The IC1 includes external terminals PNvcc, PNvss, and PNvcl that are respectively connected to the pads PDvcc, PDvss, and PDvcl of the CHP1. The BD1 includes an external capacitor CE mounted between a wiring pattern of the PNvcl and a wiring pattern of the PNvss, in addition to wiring patterns that are respectively connected to the PNvcc, PNvss, and PNvcl.

On the wiring board BD2 illustrated in FIG. 3B, a semiconductor package IC2 is mounted as an example of the semiconductor device. The IC2 is provided by packaging the semiconductor chip CHP2 of FIG. 2. The IC2 includes external terminals PNvcc, PNvss, and PNvdd that are respectively connected to the pads PDvcc, PDvss, and PDvdd of the CHP2. The BD2 includes wiring patterns that are respectively connected to the PNvcc, PNvss, and PNvdd.

For example, with the miniaturization of the process in the core circuit block CRBK, a voltage reduction of the internal power source voltage VDD is in progress. Therefore, as in FIGS. 1 and 3A, it is often the case that the power regulator circuit VREG is included in the semiconductor chip CHP1 (semiconductor package IC1). However, the power consumption of the CRBK is increased and a self heat generation amount is increased by a thermal resistance of the package in the semiconductor package including the VREG, which may cause a problem. For example, in such a case, as in FIGS. 2 and 3B, a method of directly supplying the VDD from the outside is used.

<<Schematic Configuration of Power Regulator Circuit and Surrounding>>

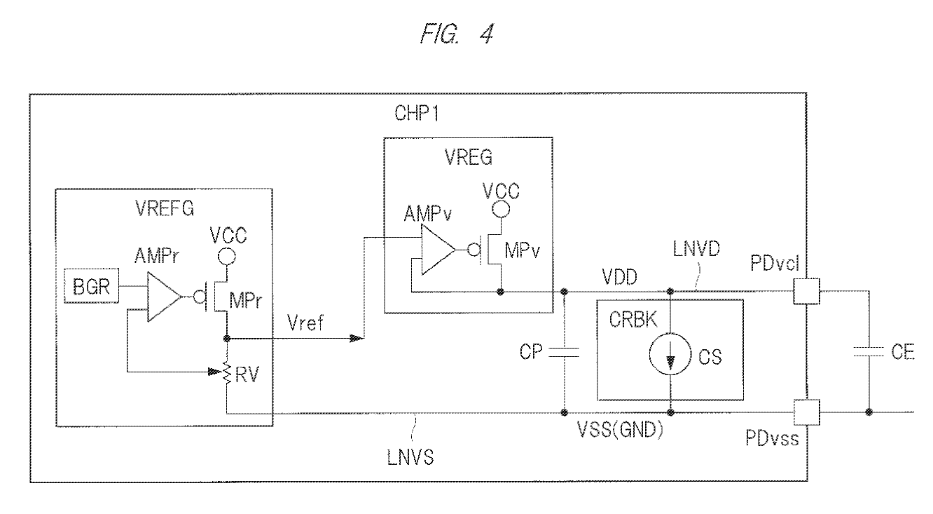

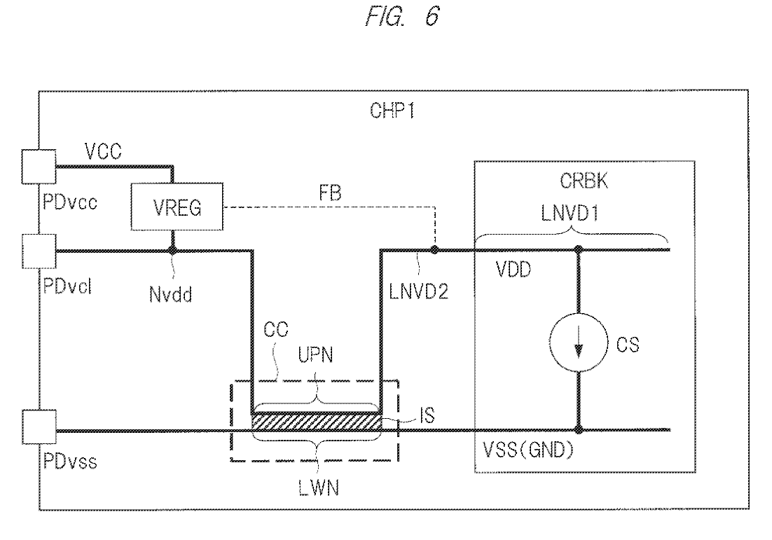

FIG. 4 is a circuit diagram illustrating an example of an equivalent circuit including a power-source voltage regulator circuit and the peripheral circuits in the semiconductor device of FIG. 1. The power-source voltage regulator circuit VREG illustrated in FIG. 6 is a linear regulator, and includes an amplifier circuit AMPv and a PMOS transistor MPv. The MPv is configured such that the power source voltage VCC is supplied to the source and the inner power source voltage VDD is output through the drain. The AMPv is configured such that a reference voltage Vref is applied to one of two inputs and the VDD (the drain of the MPv) is fed back to the other one of the two inputs so as to control the gate voltage of the MPv so that the VDD is matched with the Vref.

The reference voltage Vref is generated by a reference voltage generating circuit VREFG. The VREFG includes a bandgap reference circuit BGR, an amplifier circuit AMPr, a PMOS transistor MPr, and a variable resistor RV. The MPr is configured such that the power source voltage VCC is supplied to the source and the Vref is output from the drain. The RV functions as a so-called trimming resistor which performs a resistive voltage division between the drain voltage (Vref) of the MPr and the reference power source voltage VSS (the ground power source voltage GND) at a predetermined ratio, and corrects a variation or the like in manufacturing processes. The ratio of resistive voltage division, for example, is stored in the non-volatile memory ROM of FIG. 1 in advance. The AMPr is configured such that the output voltage of the BGR is applied to one of two inputs and the voltage at a resistive voltage division node in the RV is fed back to the other one of the two inputs so as to control the gate voltage of the MPr so that the voltage at the resistive voltage division node is matched with the output voltage of the BGR.

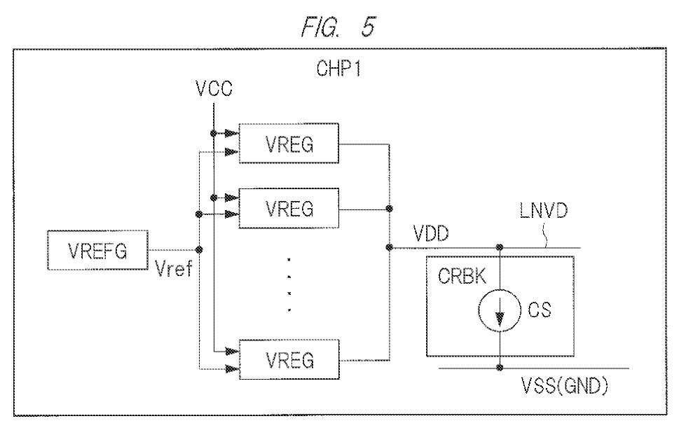

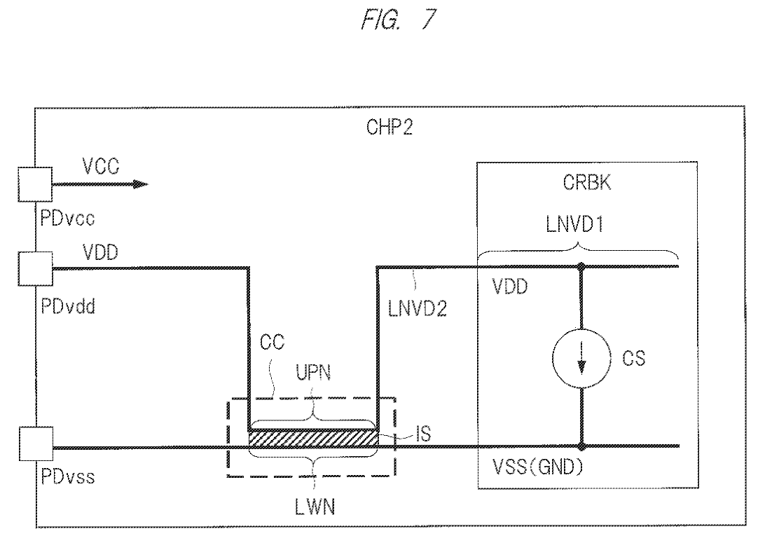

FIG. 5 is a circuit block diagram illustrating an example of an actual configuration of the peripheral circuits of the power-source voltage regulator circuit in the semiconductor device of FIG. 1. Actually, a plurality of power-source voltage regulator circuits VREG illustrated in FIG. 6 are appropriately disposed in a distributed manner in the semiconductor chip CHP as illustrated in FIG. 7. In other words, each of the plurality of VREGs receives the power source voltage VCC and the reference voltage Vref from one reference voltage generating circuit VREFG to generate the internal power source voltage VDD, and outputs the VDD to the common power-source voltage line LNVD. The number of VREGs is determined according to a current supply capability of each VREG and the current consumption of the core circuit block CRBK. Further, respective VREGs, for example, may be appropriately disposed in a distributed manner along the outer peripheral portion of the CRBK in FIG. 1.

Herein, in FIG. 4, the internal power source voltage VDD, which is generated by the power regulator circuit VREG, is supplied to the core circuit block CRBK and is output to the pad PDvcl. The CRBK can be equivalently indicated as a current source CS that is connected between the power-source voltage line LNVD, to which the VDD is supplied, and the reference power-source voltage line LNVS, to which the reference power source voltage VSS is supplied. A current value of the CS is frequently changed according to processing contents of the CRBK. The LVvdd and the LNVS actually have a parasitic resistance component. Thus, in the VDD and the VSS, a power supply noise is generated according to the change in the current value of the CS.

When such a power supply noise is generated, for example, it is apprehended that a malfunction will occur in each circuit inside the core circuit block CRBK, or the operation of the power regulator circuit VREG will be unstable, or an excessive EMI noise (emission noise) will occur in the pad PDvcl. Such a noise can be reduced to some extent by a parasitic capacitance CP existing between the power-source voltage line LNVD and the reference power-source voltage line LNVS or an external capacitor CE. The CP mainly corresponds to a wiring capacitance between the mesh-like sub power-source voltage line MLVDS illustrated in FIG. 1 and the sub reference power-source voltage line (not illustrated), or a capacitance of a diffusion layer of each transistor constituting the CRBK. However, the CP alone may not obtain as much capacitance value as nF (nanofarad) order and the capacitance value may be insufficient. Also, the CE has a certain distance with respect to the CRBK and is connected through the line. Due to a parasitic resistance component of the relevant line, the CE may not effectively function as a bypass capacitor of the CRBK.

### Overview of Semiconductor Device

### Main Part of the Present Embodiment

FIG. 6 is a schematic diagram illustrating a schematic configuration example of a main part in the semiconductor device of FIG. 1. The semiconductor chip CHP1 illustrated in FIG. 6 includes an on-chip capacitor CC, in addition to the power regulator circuit VREG and the core circuit block CRBK. The CRBK includes a power-source voltage line (first power-source voltage line) LNVD1 that is disposed inside the CRBK to supply the internal voltage VDD to each internal circuit of the CRBK. The power-source voltage line (first power-source voltage line) LNVD1 corresponds to the main power-source voltage line MLVDM and the sub power-source voltage line MLVDS in FIG. 1.

An output node of the power regulator circuit VREG is a power-source source node Nvdd. The Nvdd and the power-source voltage line (first power-source voltage line) LNVD1 are connected through a power-source voltage line (second power-source voltage line) LNVD2 that is disposed on the outside of the core circuit block CRBK. The on-chip capacitor CC has a lower electrode (second electrode) LWN to which the reference power source voltage VSS (ground power source voltage GND) is supplied, and an upper electrode (first electrode) UPN. An insulating film IS is provided between the LWN and the UPN. Herein, the CC has a partial section of the LNVD2 as the UPN.

FIG. 7 is a schematic diagram illustrating a schematic configuration example of a main part in the semiconductor device of FIG. 2. As compared with the semiconductor chip CHP1 of FIG. 6, the semiconductor chip CHP2 illustrated in FIG. 7 has a configuration in which the power regulator circuit VREG is removed. Therefore, the pad PDvdd is the power-source source node. The other configuration is similar to the case of FIG. 6. That is, as in the case of the CHP1 of FIG. 6, the on-chip capacitor CC in the CHP2 of FIG. 7 also has a partial section of the power-source voltage line (second power-source voltage line) LNVD2 as the upper electrode (first electrode) UPN.

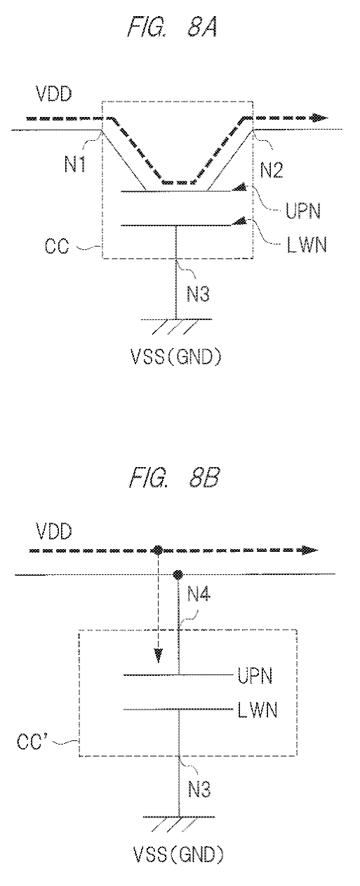

FIG. 8A is a circuit symbol schematically illustrating the on-chip capacitor in FIGS. 6 and 7, and FIG. 8B is a circuit symbol of comparative example of FIG. 8A. When using the on-chip capacitor CC having the configuration of FIGS. 6 and 7, the internal power source voltage VDD from the power-source source node Nvdd is necessarily supplied through the upper electrode (first electrode) UPN to the core circuit block CRBK. This can be indicated by the circuit symbol as illustrated in FIG. 8A. The CC illustrated in FIG. 8A has three nodes N1 to N3. For example, the CC has the N3 as the reference power source voltage VSS (ground power source voltage GND), receives the VDD from the N1, and outputs the VDD from the N2. At this time, the UPN is the power-source voltage line of the VDD directed from the N1 to the N2 and is also the electrode of the capacitor.

On the other hand, the on-chip capacitor CC′ being comparative example illustrated in FIG. 8B has two nodes N3 and N4. The N3 is the reference power source voltage VSS (ground power source voltage GND), and the N4 is connected in parallel to the power-source voltage line of the internal power source voltage VDD. Although the illustration is omitted, strictly speaking, a resistance component exists in the N4. In the on-chip capacitor CC′ of FIG. 8B, in order for the VDD to pass through the power-source voltage line having low impedance, the CC′ may not effectively function as the bypass capacitor. In other words, it is apprehended that the capacitance value effectively functioning as the bypass capacitor is a part of the capacitance value that the CC′ has. In order to make the CC′ effectively function, it is necessary to further increase the capacitance value that the CC′ has (for example, the circuit area of the CC′ is increased).

On the other hand, when using the on-chip capacitor CC of FIG. 8A, the internal power source voltage VDD necessarily passes through the upper electrode (first electrode) UPN. Thus, the CC effectively functions as the bypass capacitor. In other words, the capacitance value that the CC has is equal to the effective capacitance value functioning as the bypass capacitor. Therefore, when using the CC, for example, the same effect as the on-chip capacitor CC′ can be obtained by a capacitance value smaller than the capacitance value that the CC′ has.

The on-chip capacitors CC illustrated in FIGS. 6 and 7 function as the bypass capacitor. The bypass capacitor has a predetermined frequency component generated in the internal power source voltage VDD and has a function of reducing the power supply noise by bypassing the power supply noise on the reference power source voltage VSS side by using the impedance characteristic of the capacitor (1/(frequency×capacitance value)). In order to increase the effect as the bypass capacitor, when the capacitance value thereof is increased to some extent, it is advantageous to connect the electrode of the bypass capacitor to the noise generation source with low impedance.

When using the on-chip capacitors CC illustrated in FIGS. 6 and 7, as described above, the capacitance value as the bypass capacitor can be sufficiently secured. Therefore, in FIG. 6, the power supply noise generated in the core circuit block CRBK can be reduced. As a result, the malfunction of the CRBK is prevented, the operation of the power regulator circuit VREG is stabilized, or the EMI noise (emission noise) emitted from the pad PDvcl is reduced. Also, in FIG. 7, in addition to the reduction of the power supply noise generated in the CRBK, it is possible to reduce the power supply noise that is included in the internal power source voltage VDD supplied from the pad PDvdd.

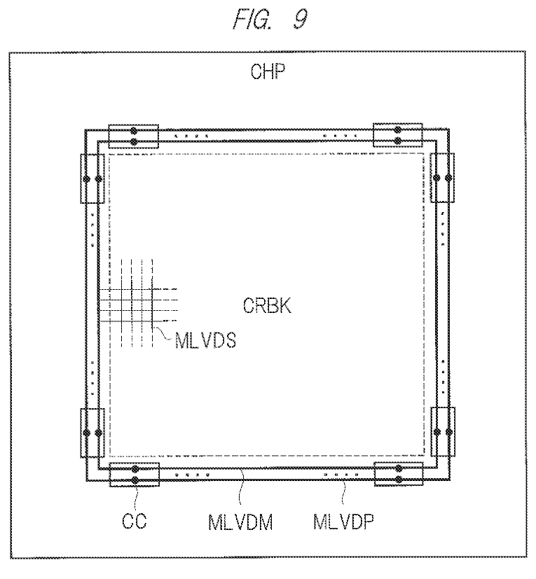

FIG. 9 is a plan view illustrating a schematic arrangement example of the on-chip capacitors in the semiconductor devices of FIGS. 6 and 7. In FIG. 9, the forming region (first region) of the core circuit block CRBK is disposed inside the semiconductor chip CHP. Also, the main power-source voltage line MLVDM is disposed along the outer peripheral portion of the first region (CRBK). Herein, the MLVDM has a ring shape and is disposed to surround the CRBK. As described with reference to FIG. 1 or the like, the sub power-source voltage line MLVDS branched from the MLVDM and disposed in a mesh shape is disposed inside the region surrounded by the MLVDM. A plurality of on-chip capacitors CC are disposed along the MLVDM. Herein, a plurality of on-chip capacitors CC are disposed to surround the CRBK. Each CC is configured by, for example, a unit cell.

A source power-source voltage line MLVDP, which is connected to the power-source source node (not illustrated) (that is, the node Nvdd of FIG. 6 or the pad PDvdd of FIG. 7), is disposed on the outside of the region surrounded by the main power-source voltage line MLVDM. Herein, the MLVDP has a ring shape that surrounds the MLVDM and is disposed to extend in parallel to the MLVDM. The plurality of on-chip capacitors CC is disposed in a region between the MLVDP and the MLVDM. In each CC, one end (node N1 of FIG. 8A) of the upper electrode (first electrode) UPN is connected to the MLVDP, and the other end (node N2 of FIG. 8A) of the UPN is connected to the MLVDM.

When using such an arrangement example, the supply of the internal power source voltage VDD from the power-source source node to the core circuit block CRBK is all performed through the upper electrodes (first electrodes) UPN of the on-chip capacitors CC. That is, as illustrated in FIG. 8B, the power supply path can be excluded such that the internal power source voltage VDD passes. Furthermore, herein, since the plurality of CCs is disposed to surround the CRBK along the main power-source voltage line MLVDM, the effect as the bypass capacitor corresponding to the CRBK of the CC can be further increased.

Specifically, as described above, in order to increase the effect as the bypass capacitor, it is suitable to connect the electrode of the bypass capacitor to the generation source of the power supply noise with lower impedance (that is, shorter line length). If using the arrangement example of FIG. 9, even when the power supply noise is generated at any place inside the core circuit block CRBK, that is connected to the electrode of the bypass capacitor with low impedance and the power supply noise can be bypassed by using the bypass capacitor in which the capacitance value is sufficiently secured.

Also, herein, the on-chip capacitor CC is formed using a unit cell, instead of forming the capacitance by using the general power-source voltage line as it is, as described in Patent Document 2. Therefore, the necessary capacitance value can be sufficiently secured without unnecessarily increasing the length of the power-source voltage line (for example, LNVD2 of FIG. 6). That is, when the length of the power-source voltage line is increased, it is apprehended that the power supply noise will be increased by the IR drop. However, when the unit cell is used, such a situation can be prevented. Furthermore, when the unit cell is used, the layout design can be automatically carried out, thereby facilitating the design.

<<Type of ON-Chip Capacitor>>

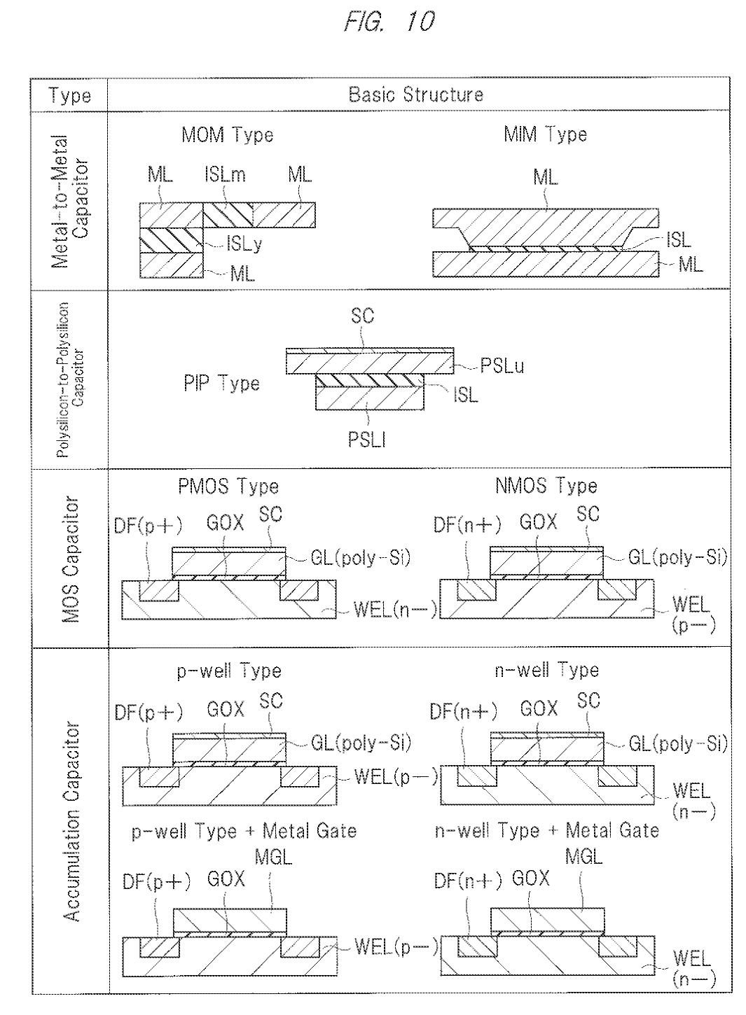

FIG. 10 is a diagram schematically illustrating various structures of the on-chip capacitor in the semiconductor device of FIGS. 6 and 7. In FIG. 10, first, as an on-chip capacitor CC using capacitance between metal lines, a MOM type capacitor and a MIM type capacitor can be exemplified. The MOM type capacitor has a structure in which metal lines ML are closely disposed in the same metal line layer and a metal-to-metal insulating film ISLm therebetween is used as a capacitor, and the MLs are disposed in an overlapping manner in different metal line layers to use an interlayer insulating film ISLy therebetween as a capacitor. The MIM type capacitor has a structure in which the metal lines ML are overlapped with a thin insulating film ISL disposed therebetween.

Since the metal line ML is used as the electrode, a parasitic resistance (equivalent series resistance (ESR)) of the electrode is small, and a merit as the bypass capacitor is provided. Furthermore, in the on-chip capacitor according to the present embodiment, since the electrode is a part of the power-source voltage line and the IR drop of the power-source voltage line is reduced, or since the ability to supply the current to the core circuit block CRBK can be sufficiently secured, it is suitable that the electrode has a resistance as low as possible. From this point, a MOM type and a MIM type have a merit. However, as compared with the MOM type, the MIM type can increase the capacitance value per unit area, but cannot be achieved by a general CMOS process. Since a special process is required, the use of the MOM type is more preferable in terms of manufacturing costs.

Next, as an on-chip capacitor CC using a capacitor between polysilicon layers, a PIP type capacitor can be exemplified. The PIP type capacitor has a structure in which the insulating film ISL is mounted on a polysilicon layer PSL1 of a lower layer and a polysilicon layer PSLu is mounted on an upper layer thereof. A silicide layer SC is formed on the PSLu. The PIP type capacitor has a complicated process structure and the polysilicon electrode (specifically, on a side near the lower layer) has a large equivalent series resistance. Therefore, the above-mentioned MOM type capacitor is desirable.

Subsequently, as an on-chip capacitor CC using a MOS capacitance, a PMOS type capacitor and a NMOS type capacitor can be exemplified. The PMOS type capacitor has a structure in which a p-type diffusion layer DF(p+) for the source and the drain is formed in an n-type well WEL(n−1) and a gate line GL is mounted on the WEL(n−1) via a gate insulating film GOX. The NMOS type capacitor has a structure in which an n-type diffusion layer DF(n+) for the source and the drain is formed in a p-type well WEL(p−) and the gate line GL is mounted on the WEL(p−) via the gate insulating film GOX. In addition, for example, the GL as well as the PMOS type capacitor and the NMOS type capacitor is formed of polysilicon, and the silicide layer SC is formed on the GL.

The PMOS type capacitor and the NMOS type capacitor can be made to have a large capacitance value per unit region, but has a demerit that the equivalent series resistance of the electrode is large. In other words, one electrode has a large equivalent series resistance due to the gate line GL (that is, polysilicon), but the equivalent series resistance can be lowered by the silicide layer SC to some degree. However, since the other electrode serves as a channel portion in the well WEL, the equivalent series resistance of the portion is easily lowered. Therefore, the above-mentioned MOM type capacitor is desirable.

Finally, as an on-chip capacitor CC using an accumulation capacitor, a p-well type capacitor, an n-well type capacitor, and capacitors in which the metal gate is combined with these capacitors can be exemplified. The p-well type capacitor has a structure in which a p-type diffusion layer DF(p+) having impurity concentration higher than that of the p-type well WEL(p−) is formed in the p-type well and the gate line GL is mounted on the WEL(p−) via the gate insulating film GOX. The n-well type capacitor has a structure in which an n-type diffusion layer DF(n+) having impurity concentration higher than that of the n-type well WEL(n−) is formed in the n-type well and the gate line GL is mounted on the WEL(n−) via the gate insulating film GOX. In addition, for example, the GL as well as the p-well type capacitor and the n-well type capacitor is formed of polysilicon, and the silicide layer SC is formed on the GL. The p-well type capacitor and the n-well type capacitor are structured to be changed in polarity of the diffusion layer in the above-mentioned NMOS type capacitor and PMOS type capacitor. Such a structure will be referred to as an accumulation capacitor in this specification.

Unlike the case of the PMOS type capacitor and the NMOS type capacitor, the accumulation capacitor has the other electrode (for example, the lower electrode LWN in FIG. 6) which is formed as a well WEL, so that the equivalent series resistance, for example, can be reduced by increasing the region of the WEL. Therefore, it is favorable that the accumulation capacitor be used as the on-chip capacitor CC besides the above-mentioned MOM type capacitor. However, similarly to the case of the above-mentioned PMOS type capacitor and NMOS type capacitor, there is a concern that the accumulation capacitor causes an equivalent series resistance to some degree in one electrode (for example, the upper electrode UPN in FIG. 6). Therefore, it is desirable to use a structure in which the gate line GL in the p-well type capacitor and the n-well type capacitor is replaced with a metal gate line MGL. The MGL, for example, is formed using a metal material such as titanium (Ti).

By using the semiconductor device of the present first embodiment, representatively, the reduction of noise (power supply noise, EMI noise (emission noise)) can be achieved.

### Second Embodiment

In the present second embodiment, a case where an accumulation capacitance is used as the on-chip capacitor CC described in the first embodiment and the internal power source voltage VDD is supplied from the outside will be exemplarily described in detail.

### Details [1] of Semiconductor Device

### Main Part of Present Embodiment

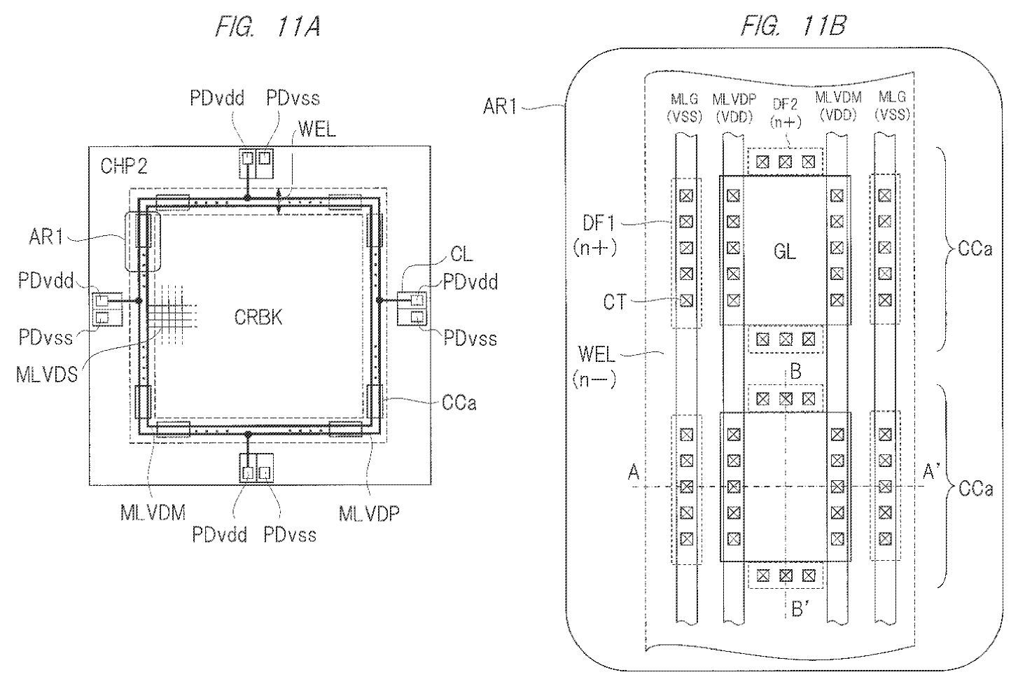

FIG. 11A is a plan view illustrating a schematic arrangement example of an on-chip capacitor inside a semiconductor chip in a semiconductor device according to the second embodiment of the present invention, and FIG. 11B is a plan view illustrating a detailed layout configuration example of a partial region in FIG. 11A. FIG. 11A illustrates a schematic arrangement example of the on-chip capacitor CCa, for example, in a case where the semiconductor chip CHP2 of FIG. 7 as described above is used.

A forming region (first region) of a core circuit block CRBK is disposed inside the semiconductor chip CHP2 illustrated in FIG. 11A. Also, a main power-source voltage line MLVDM is disposed along an outer peripheral portion of the first region (CRBK). Herein, the MLVDM has a ring shape and is disposed to surround the CRBK. As described with reference to FIG. 1 or the like, a sub power-source voltage line MLVDS branched from the MLVDM and disposed in a mesh shape is disposed inside the region surrounded by the MLVDM. A plurality of on-chip capacitors CCa are disposed along the MLVDM. Herein, a plurality of on-chip capacitors CCa are disposed to surround the CRBK. Each CCa is configured by, for example, a unit cell.

A source power-source voltage line MLVDP is disposed on the outside of the region surrounded by the main power-source voltage line MLVDM. The MLVDP is connected to a pad PDvdd that is a power-source source node. Herein, the MLVDP has a ring shape that surrounds the MLVDM and is disposed to extend in parallel to the MLVDM. The PDvdd is disposed inside a cell CL for external input/output. An electro static discharge (ESD) protection element or the like is formed in the CL. The plurality of on-chip capacitors CCa is disposed in a region between the MLVDP and the MLVDM. Also, a region of a well WEL is formed to include the region where the on-chip capacitor CCa is disposed. Herein, the region of the well WEL is a river-shaped region.

FIG. 11B illustrates details of a region AR1 including the on-chip capacitor CCa in FIG. 11A. In FIG. 11B, an n-type well WEL (n−) is disposed to form the river-shaped region by two edges extending in parallel. In the region of the WEL (n−), herein, two on-chip capacitors CCa are disposed at a predetermined interval in an extending direction of the region. Each CCa includes a rectangular gate line GL, two n-type diffusion layers (first semiconductor region) DF1 (n+) having a higher impurity concentration than the WEL (n−), and two n-type diffusion layers (first semiconductor region) DF2 (n+) having a higher impurity concentration than the WEL (n−). The GL has a first edge and a second edge extending in parallel to the two edges of the region of the WEL (n−), and a third edge and a fourth edge extending in parallel in a direction perpendicular to the two edges of the region of the WEL (n−).

In the well WEL (n−), the two diffusion layers DF1 (n+) are formed between the first edge and the second edge in the gate line GL and the two edges of the region of the WEL (n−), respectively. The two diffusion layers DF2 (n+) are formed to be close to the third edge and the fourth edge in the GL, respectively. A plurality of contact layers CT are disposed in the two diffusion layers DF1 (n+) and the two diffusion layers DF2 (n+), respectively. Also, a plurality of contact layers CT are disposed around the first to fourth edges, respectively.

Furthermore, in FIG. 11B, two reference power-source voltage lines MLG, one source power-source voltage line MLVDP, and one main power-source voltage line MLVDM are disposed. Each of the two MLGs, the MLVDP, and the MLVDM extends in the same direction as the extending direction of the region of the well WEL (n−). The two MLGs are disposed such that the MLVDP and the MLVDM are interposed therebetween. The two MLGs are connected to the contact layers CT disposed in the two diffusion layers DF1 (n+), respectively. The MLVDP and the MLVDM are connected to the contact layers CT disposed around the first edge and the second edge in the gate line GL, respectively. Also, although the illustration is omitted, for example, reference power-source voltage lines branched from the MLG are connected to the contact layers CT disposed in the two diffusion layers DF2 (n+).

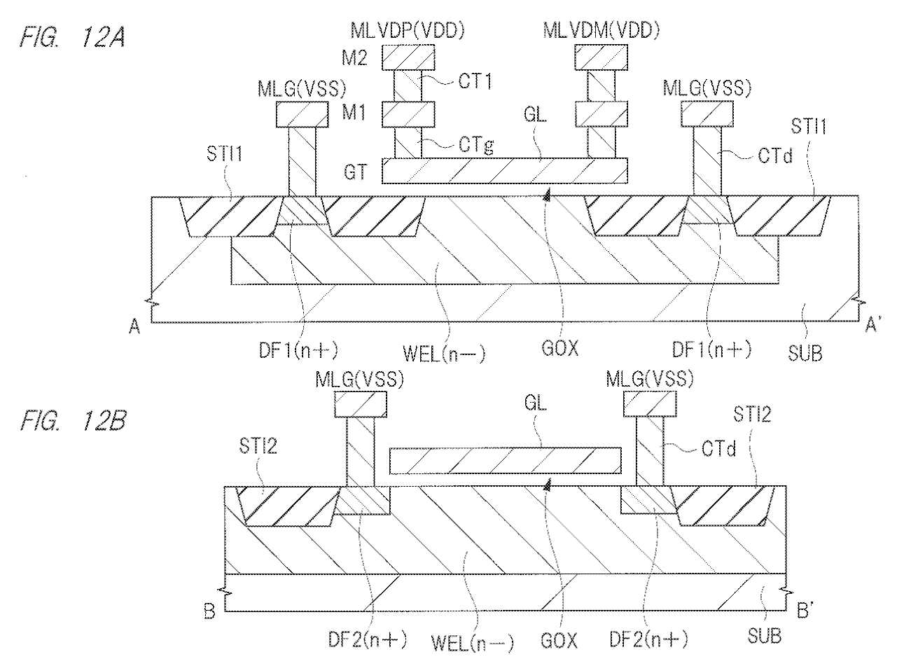

FIG. 12A is a cross-sectional view illustrating a configuration example between A-A′ in FIG. 11B, and FIG. 12B is a cross-sectional view illustrating a configuration example between B-B′ in FIG. 11B. In FIG. 12A, the n-type well WEL(n−) is formed in the semiconductor substrate SUB. In the WEL(n−), two n-type diffusion layers DF1(n+) having the impurity concentration higher than that of the WEL(n−) are formed. In a region interposed by the two n-type diffusion layers DF1(n+), two element-separation insulating films STI1 are disposed adjacent to each of the two n-type diffusion layers DF1(n+).

The gate line GL is formed via the gate insulating film GOX over the region interposed by two element-separation insulating films STI1 in the well WEL(n−). The GL is positioned in a gate layer GT, and is formed in a laminated structure of the polysilicon layer and the silicide layer for example. The GOX, for example, is formed of silicon dioxide (SiO₂). The silicide layer, for example, is formed of tungsten (W), molybdenum (Mo), titanium (Ti) or the like.

Both ends of the gate line GL each are connected to two metal lines in the first metal line layer M1 through the contact layers CTg, and the two metal lines each are connected to two metal lines in the second metal line layer M2 through the contact layers CT1. One of the two metal lines in the M2 serves as the main power-source voltage line MLVDP, and the other one serves as the main power-source voltage line MLVDM. Further, the two diffusion layers DF1(n+) each is connected to two metal lines in the M1 through the contact layers CTd. Both of the two metal lines in the M1 serve as reference power-source voltage line MLG. In addition, the metal line is formed of cupper (Cu) or the like for example.

In FIG. 12B, the n-type well WEL(n−) is formed in the semiconductor substrate SUB. Two n-type diffusion layers DF2 (n+) having impurity concentration higher than that of the WEL (n−) are formed in the WEL (n−). Further, in the WEL (n−), two element-separation insulating films STI2 are disposed adjacent to each of the two n-type diffusion layers DF2 (n+) so as to interpose the two n-type diffusion layers DF2 (n+). The gate line GL is formed via the gate insulating film GOX over the region interposed by the two n-type diffusion layers DF2 (n+) in the WEL (n−). The two n-type diffusion layers DF2 (n+) each are connected to two metal lines in the M1 through the contact layers CTd. The two metal lines in the M1 serve as the reference power-source voltage line MLG although they are omitted in FIG. 11B.

<<Equivalent Circuit of on-Chip Capacitor>>

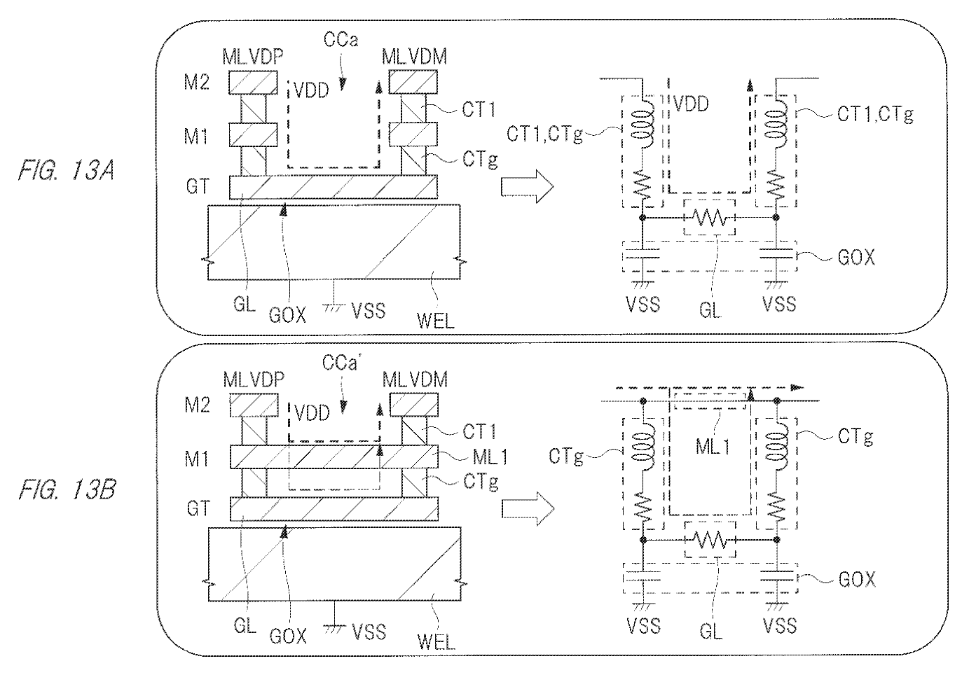

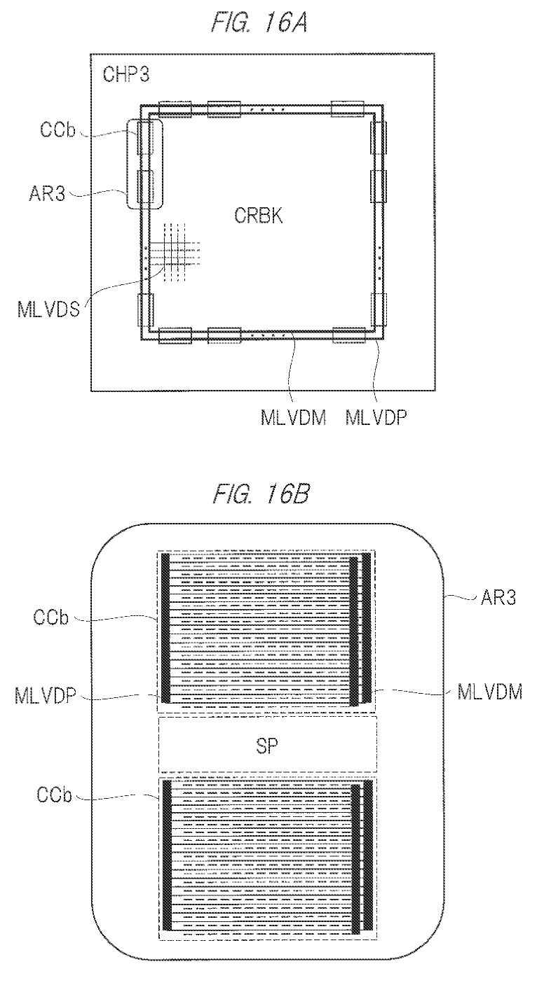

FIG. 13A is a diagram illustrating an example of the simplified cross-sectional structure of FIG. 12A and the equivalent circuit thereof, and FIG. 13B is a diagram illustrating an example of a cross-sectional structure as a comparative example of FIG. 13A and the equivalent circuit thereof. As illustrated in FIGS. 12A and 16B, the reference power source voltage VSS (the ground power source voltage GND) is supplied to the well WEL (n−) through the reference power-source voltage line MLG and the diffusion layers DF1 (n+) and DF2 (n+). Then, in the on-chip capacitor CCa of FIG. 13A, the well WEL is connected to the VSS. For example, with reference to FIG. 8A, the WEL in FIG. 13A serves as the lower electrode (the second electrode) LWN of the CCa, and the gate line GL in FIG. 13A serves as the upper electrode (the first electrode) UPN of the CCa.

As illustrated in FIG. 13A, the internal power source voltage VDD containing the power source noise supplied from the source power-source voltage line MLVDP reaches one end of the gate line GL through the contact layers CT1 and CTg, and after passing through the GL, reaches the main power-source voltage line MLVDM from the other end of the GL through the CTg and the CT1. In this case, having an equivalent series resistance component and a parasitic inductance component to some degree, the CTg and the CT1 are expressed as a series circuit of an inductor and a resistor in the equivalent circuit. Further, the GL has an equivalent series resistance component to some degree, and thus expressed as a resistor in the equivalent circuit. However, even though such parasitic components are present, there is only the GL in the supply path of the internal power source voltage VDD, so that the VDD certainly passes through the GL serving as the upper electrode of the on-chip capacitor CCa. Therefore, the CCa effectively operates as the bypass capacitor.

On the other hand, the on-chip capacitor CCa′ of FIG. 13B according to the comparative example includes a structure in which two metal lines in the first metal line layer M1 in FIG. 13A are commonly connected through a metal line ML1 in the M1. Such a structure corresponds to the circuit symbol as illustrated in FIG. 8B. In this case, much of the internal power source voltage VDD containing the power source noise supplied from the source power-source voltage line MLVDP reaches the main power-source voltage line MLVDM in the path through the ML1. Therefore, the CCa′ acts a weak operation as the bypass capacitor compared to the CCa.

<<Structure of Metal Gate>>

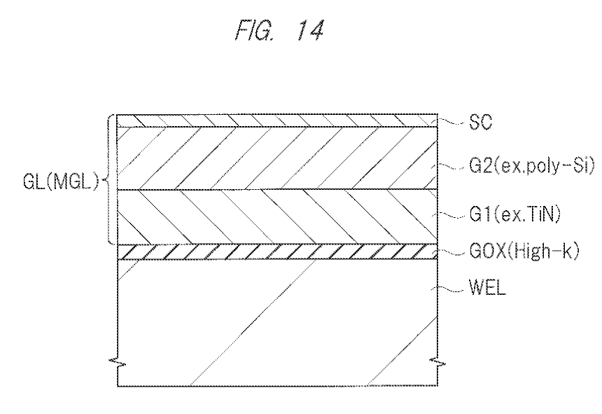

FIG. 14 is a cross-sectional view illustrating an exemplary structure of a metal gate which is used as a gate line of the on-chip capacitor of FIGS. 12A and 12B. As already described with reference to FIG. 13A etc., the gate line GL serves as the power-source voltage line of the internal power source voltage VDD and also as the electrode of the capacitor. Therefore, it is desirable that the equivalent series resistance be lowered. Then, the gate line GL, for example, is desirably formed in the metal gate structure as illustrated in FIG. 14 rather than the laminating structure of the polysilicon layer and the silicide layer.

The gate line GL (the metal gate line MGL) illustrated in FIG. 14 has a structure in which three layers (G1, G2, and SC) are sequentially laminated from a side near the gate insulating film GOX. For example, the layer G1 is formed of titanium nitride (TiN), the layer G2 is formed of polysilicon, and the silicide layer SC is formed using nickel platinum. In addition, the SC may be formed using any one of nickel (Ni), titanium (Ti), cobalt (Co), platinum (Pt). Further, the GOX is formed of a high dielectric constant gate insulating film (so-called High-k). Specifically, hafnium oxide (HfO₂) having lanthanum oxide (La₂O₃) introduced therein, hafnium silicate oxide, hafnium silicate oxynitride, and the like can be exemplified.

In addition, as the process is miniaturized and the operating speed is increased, the respective transistors in the core circuit block CRBK tend to be manufactured using such a metal gate. Further, when the process is miniaturized and the operating speed is increased, the influence of noises (the power source noise and the EMI noise) tends to be remarkably exhibited. Therefore, it is desirable to employ the metal gate for both the respective transistors in the CRBK and the on-chip capacitor CCa. In this case, when the metal gate is formed in the respective transistors in the CRBK, the metal gate is also formed in the CCa in the same process, so that manufacturing cost or the like can be saved.

By using the semiconductor device of the present second embodiment, it is possible to achieve the on-chip capacitor efficiently operating as the bypass capacitor, in addition to the effect described in the first embodiment. In particular, in the case of using the metal gate, the parasitic resistance value of the electrode is reduced and the capacitance value of the insulating film is increased, the operation as the bypass capacitor can be further improved. Also, since the on-chip capacitor is configured by the unit cell, the on-chip capacitor can be efficiently disposed around the core circuit block CRBK by the so-called self-aligned line.

Also, in FIG. 11B, from the viewpoint that reduces the parasitic resistance component of the GL, it is preferable that the gate line GL has a longitudinal shape rather than a square shape. That is, a distance (transverse direction in the example of FIG. 11B) where the internal power source voltage VDD flows in the GL is shortened and a width (longitudinal direction in the example of FIG. 11B) where the VDD flows is widened. Also, for example, in the example of FIG. 11B, the n-type well is used as the well, but a p-type well can also be used according to circumstances. That is, the p-well type structure illustrated in FIG. 10 can be used. However, since the n-type well has a smaller parasitic resistance value than the p-type well, the use of the n-type well is desirable in terms of the reduction in the resistance of the electrode. Also, in terms of the reduction in the resistance of the well, for example, in FIG. 11A, it is also advantageous to increase the river width of the river-shaped region constituting the well WEL. That is, the edge of the outer peripheral side of the semiconductor chip CHP2 in the WEL is disposed closer to the outer peripheral side of the CHP2.

### Third Embodiment

In the present third embodiment, a case where an accumulation capacitance is used as the on-chip capacitor CC described in the first embodiment and an internal power source voltage VDD is generated by an internal power regulator circuit VREG will be exemplarily described in detail. The following description will focus on a difference from the second embodiment, but the description about the on-chip capacitor described in the second embodiment also corresponds to the present third embodiment.

### Details [2] of Semiconductor Device

### Main Part of the Present Embodiment

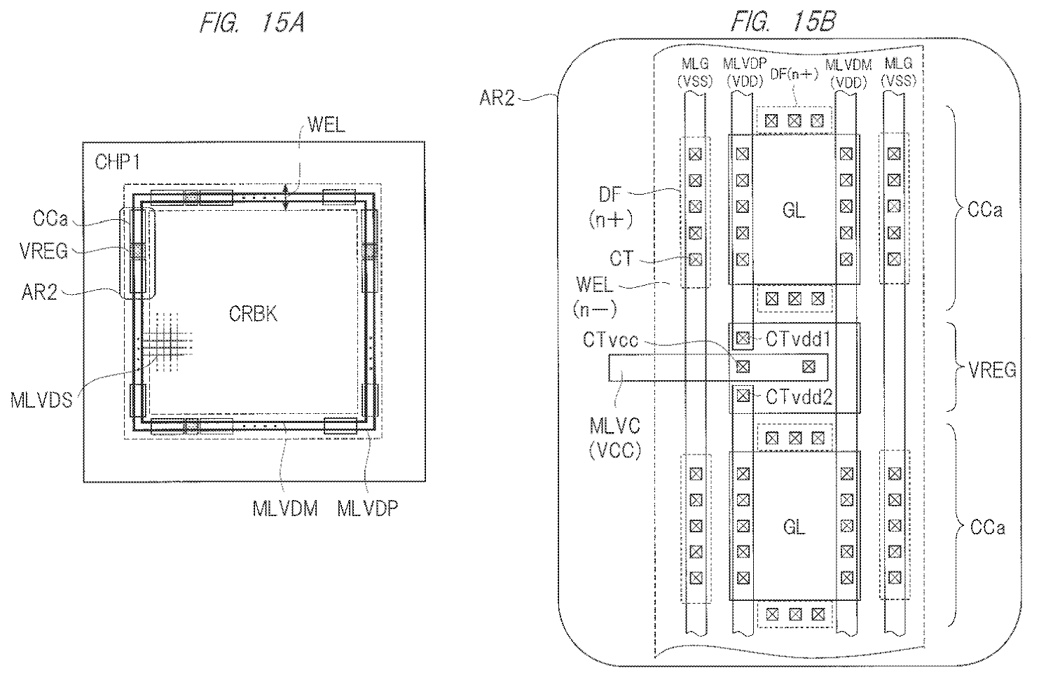

FIG. 15A is a plan view illustrating a schematic arrangement example of an on-chip capacitor and a power regulator circuit inside a semiconductor chip in a semiconductor device according to the third embodiment of the present invention, and FIG. 15B is a plan view illustrating a detailed layout configuration example of a partial region in FIG. 15A. FIG. 15A illustrates a schematic arrangement example of the on-chip capacitor CCa and the power regulator circuit VREG, for example, in the case of using the semiconductor chip CHP1 of FIG. 6 as described above.

The semiconductor chip CHP1 illustrated in FIG. 15A has substantially the same arrangement configuration as the semiconductor chip CHP2 illustrated in FIG. 11A. The CHP1 of FIG. 15A differs from the CHP2 of FIG. 11A in that the power supply path directed from the pad PDvdd toward the source power-source voltage line MLVDP in FIG. 11A is removed in FIG. 15A, and the power regulator circuit VREG is included instead of the power supply path. The VREG is appropriately disposed between the plurality of on-chip capacitors CCa disposed along the extending direction of the region of the well WEL.

FIG. 15B illustrates details of a region AR2 including the on-chip capacitor CCa and the power regulator circuit VREG in FIG. 15A. In FIG. 15B, the layout configuration of the CCa is similar to the case of FIG. 11B. However, in FIG. 15B, the VREG is disposed between the adjacent on-chip capacitors CCa and the source power-source voltage line MLVDP extends from the VREG.

Herein, a contact layer CTvcc to which the power source voltage VCC is supplied, a contact layer CTvdd1 for supplying the internal power source voltage VDD to one adjacent CCa, and a contact layer CTvdd2 for supplying the VDD to the other adjacent CCa are disposed on a forming region of the power regulator circuit VREG. The VCC is supplied to the CTvcc through the external power-source voltage line MLVC extending in a direction intersecting with the extending direction of the region of the well WEL. The VDD, which is output from the CTvdd1 and the CTvdd2, is supplied through the source power-source voltage line MLVDP extending in the same direction as the extending direction of the region of the WEL.

Also, in the example, the source power-source voltage line MLVDP is divided at the position of the power regulator circuit VREG, but is connected in the inside of the VREG through the contact layers CTvdd1 and CTvdd2. Also, it is apparent that the present invention is not limited to such a layout configuration example. By appropriately adjusting the metal line layer of the external power-source voltage line MLVC, the layout can be carried out such that the MLVDP is not divided. Also, as described with reference to FIG. 5, the number of the VREGs to be installed is appropriately set. Therefore, the number of the on-chip capacitors CCa interposed between the VREGs is determined such that the VREGs are substantially uniformly installed around the core circuit blocks CRBK corresponding to the number.

By using such a configuration example, the efficient layout can be achieved. Specifically, for example, in a case where the power regulator circuit VREG is disposed at a position different from a region where the on-chip capacitor CCa is disposed, it is apprehended that a distance from the VREG to the source power-source voltage line MLVDP will be extended, or the area of the semiconductor chip is increased. When the layouts as illustrated in FIGS. 15A and 15B are used, the above problems do not occur.

Also, for example, a single power regulator circuit VREG is disposed with respect to a plurality of on-chip capacitors CCa. The single VREG is much smaller in the circuit area than the single CCa. Therefore, in a case where the VREG is disposed at a position different from a region where the CCa is disposed, it is apprehended that a great height difference will occur in the region where the VREG is disposed. On the other hand, in a case where the VREG is disposed between a plurality of on-chip capacitors CCa, since the VREG is much smaller in the circuit area than the CCa, two on-chip capacitors CCa adjacent to the VREG are disposed at a close distance, and therefore, the height difference occurring in the region where the VREG is disposed is reduced.

Also, in practice, a PMOS transistor MPv illustrated in FIG. 4 is formed in the region where the power regulator circuit VREG illustrated in FIG. 15B is disposed. The MPv occupies almost all area in the VREG. Regarding an amplifier circuit AMPv of FIG. 6, generally, since a p-type well as well as an n-type well is required, for example, it is not separately formed in a position close to the region where the VREG of FIG. 15B is disposed. Since the area of the AMPv is negligibly small as compared with the MPv, there is no relation to, in particular, the efficiency of the layout.

### Fourth Embodiment

In the present fourth embodiment, a case where a MOM-type inter-metal capacitance is used as the on-chip capacitor CC described in the first embodiment will be exemplarily described in detail.

### Details [3] of Semiconductor Device

### Main Part of Present Embodiment

FIG. 16A is a plan view illustrating a schematic arrangement example of an on-chip capacitor inside a semiconductor chip in a semiconductor device according to the third embodiment of the present invention, and FIG. 16B is a plan view illustrating a detailed layout configuration example of a partial region of FIG. 16A. The semiconductor chip CHP3 illustrated in FIG. 16A has a similar arrangement structure to the semiconductor chip CHP illustrated in FIG. 9 of the first embodiment. That is, in the region between the source power-source voltage line MLVDP and the main power-source voltage line MLVDM, a plurality of on-chip capacitors CCb are disposed along the extending direction of the MLVDP and the MLVDM.

FIG. 16A illustrates details of a region AR3 including the on-chip capacitors CCb in FIG. 16A. As illustrated in FIG. 16B, the on-chip capacitors CCb are disposed along the extending direction of the MLVDP and the MLVDM, with a predetermined region SP being interposed therebetween. For example, various signal lines or the like, which are directed from a core circuit block CRBK toward a pad (not illustrated) of the semiconductor chip CHP3, are formed in the region SP. Although described below in detail, the CCb is formed by using most of the metal layer, for example. Therefore, in this example, a passage region of the various signal lines or the like is secured by the SP.

Also, in FIG. 16B, each of the source power-source voltage line MLVDP and the main power-source voltage line MLVDM is divided between the respective on-chip capacitors CCb, but is practically connected by using appropriately the metal line layer. Also, in FIG. 16A, a description about the power-source source node is omitted. In a case where the power-source source node is a pad, the MLVDP is configured to be connected to the pad PDvdd as illustrated in FIG. 11A. In a case where the power-source source node is a power regulator circuit, the power regulator circuit VREG is appropriately disposed as illustrated in FIG. 15A, and the output thereof is configured to be connected to the MLVDP. At this time, the region where the VREG is disposed may be the region SP in FIG. 16B or may be the region around the CCb, except for the SP.

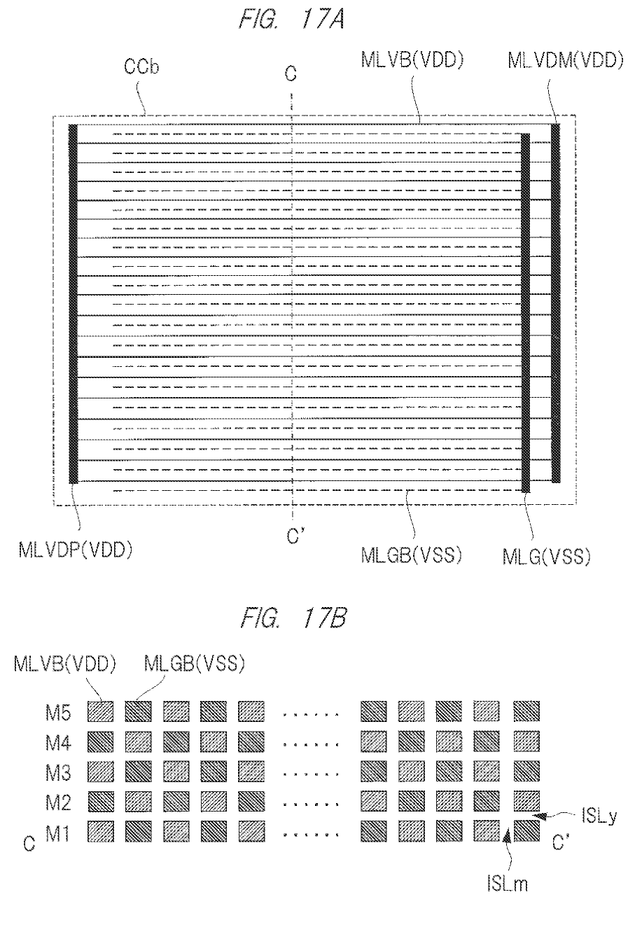

FIG. 17A is a plan view illustrating a detailed layout configuration example of each on-chip capacitor in FIG. 16B, and FIG. 17B is a cross-sectional view illustrating a configuration example between C-C′ in FIG. 17A. As illustrated in FIG. 17A, the on-chip capacitor CCb includes a source power-source voltage line MLVDP, a main power-source voltage line MLVDM, a reference power-source voltage line MLG, a plurality of branch power-source voltage lines MLVB, and a plurality of branch reference power-source voltage lines MLGB. The MLVDP, the MLVDM, and the MLG extend in parallel in the same direction. The plurality of MLVB and MLGB extends in parallel in a direction (first direction) intersecting with the extending direction of the MLVDP, the MLVDM, and the MLG.

The plurality of branch power-source voltage lines (first metal line) MLVB has one end commonly connected to the source power-source voltage line (first node) MLVDP, and the other end commonly connected the main power-source voltage line (second node) MLVDM. The plurality of branch reference power-source voltage lines (second metal line) MLGB has one end commonly connected to the reference power-source voltage line MLG and is disposed at predetermined intervals such that an insulating film (not illustrated) is interposed with respect to the plurality of MLVB. Also, herein, the MLG is disposed on one end side of the MLGB. However, as in the case of the MLVB, the MLG may be disposed on the other end side of the MLGB. For example, the plurality of MLVB and MLGB is formed by lines that are thinner than the MLVDP, the MLVDM, and the MLG.

As illustrated in FIG. 17B, the on-chip capacitor CCb of FIG. 17A is formed by using a multi-layered metal line layer on a semiconductor substrate (not illustrated), an inter-metal-line insulating film dividing the respective metal lines in the same metal line layers, and an interlayer insulating film dividing different metal line layers. In this example, the same layout rule (that is, the rule of the minimum line width or the minimum inter-line pitch is equal) is applied to the first metal line layer M1 to the fifth metal line layer M5 sequentially disposed toward the upper layer, and the CCb is formed by using the M1 to the M5, the inter-metal-line insulating film ISLm, and the interlayer insulating film ISLy.

In FIG. 17B, in the same layer of the multi-layered metal line layers (M1 to M5), each branch power-source voltage line (first metal line) MLVB and each branch reference power-source voltage line (second metal line) MLGB are alternately disposed, with the inter-metal-line insulating film ISLm being interposed therebetween. Furthermore, even in the layer direction of the multi-layered metal line layers (M1 to M5), each MLVB and each MLGB are alternately disposed, with the interlayer insulating film ISLy being interposed therebetween. With reference to the FIGS. 6 and 7 described above, the plurality of MLVB constitutes the upper electrode (first electrode) UPN, and the plurality of MLGB constitutes the lower electrode (second electrode) LWN. In particular, although not limited thereto, the MLVB and the MLGB are formed in the same metal line layer by the minimum inter-line pitch of the layout rule.

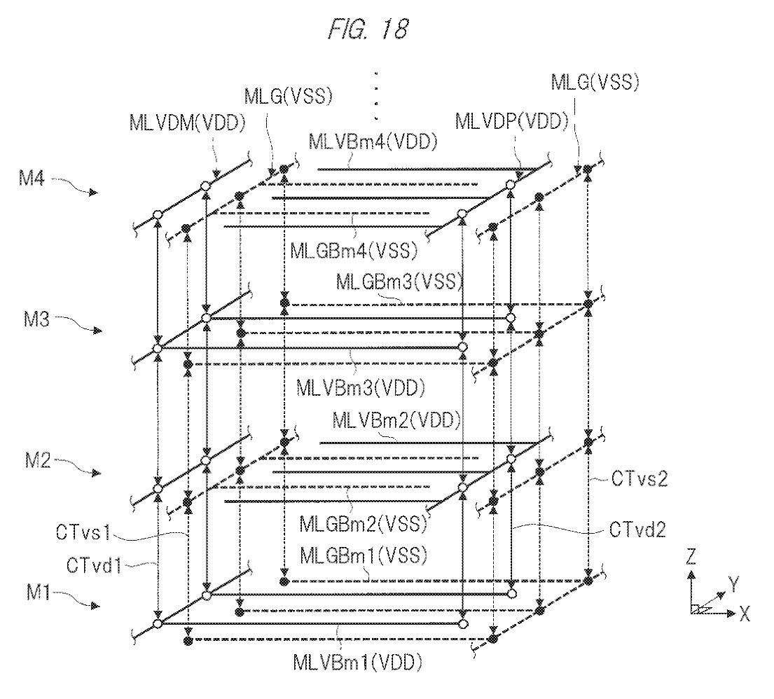

FIG. 18 is a three-dimensional view schematically illustrating a configuration example of a part in the on-chip capacitors of FIGS. 17A and 17B. In the example of FIG. 18, first, regarding the power-source voltage line, by using the main power-source voltage line MLVDM of the core circuit block side as a comb in the first metal line layer M1 and the plurality of branch power-source voltage lines MLVBm1 as teeth, the power-source voltage lines having a comb-tooth shape are disposed such that a plurality of teeth are branched from the comb. On the other hand, in the second metal line layer M2, by using the source power-source voltage line MLVDP as a comb and the plurality of branch power-source voltage lines MLVBm2 as teeth, the comb-tooth-shaped power-source voltage lines are disposed. Also, a power-source voltage line for interlayer connection, which has the same XY coordinates as the MLVDM of the M1, is disposed in the M2.

The comb-tooth-shaped power-source voltage line inside the second metal line layer M2 folds back the comb-tooth-shaped power-source voltage line inside the first metal line layer M1 symmetrically to the Y-axis, and the XY coordinates of the teeth are shifted by a predetermined pitch in the Y-axis direction. In addition, the length of the teeth in the X-axis direction is formed to be small as compared with the teeth inside the M1. Herein, the predetermined pitch is an interval between the branch power-source voltage line MLVB and the branch reference power-source voltage line MLGB that are mutually adjacent within the same metal line layer.

In the comb-tooth-shaped power-source voltage line inside the first metal line layer M1, one end of the contact layer CTvd2 is connected to the front end of the plurality of teeth branched from the comb. In the comb-tooth-shaped power-source voltage line inside the second metal line layer M2, the other end of the CTvd2 is connected to a middle position between the branch point of the tooth from the comb and the branch point of the adjacent tooth from the comb. Furthermore, in the comb-tooth-shaped power-source voltage line inside the M1, one end of the contact layer CTvd1 is connected to a predetermined position on the comb (herein, branch points of the plurality of teeth). In the inside of the M2, the other end of the CTvd1 is connected to the power-source voltage line for interlayer connection.

Similarly, in odd metal line layers, the comb-tooth-shaped power-source voltage line having the same XY coordinates as the comb-tooth-shaped power-source voltage line inside the first metal line layer M1 is disposed. In even metal line layers, the comb-tooth-shaped power-source voltage line and the power-source voltage line for interlayer connection, which have the same XY coordinates as the comb-tooth-shaped power-source voltage line and the power-source voltage line for interlayer connection inside the second metal line layer M2, are disposed. The power-source voltage lines are appropriately connected to the CTvd1 and the CTvd2 having the same XY coordinates as the above-described contact layers CTvd1 and CTvd2, respectively.

Next, regarding the reference power-source voltage line, the comb-tooth-shaped power-source voltage line inside the above-described odd metal line layers is folded back symmetrically to the Y-axis, and the comb-tooth-shaped reference power-source voltage line is disposed such that the XY coordinates of the teeth are shifted by a predetermined pitch in the Y-axis direction. The comb-tooth-shaped reference power-source voltage line is configured by a reference power-source voltage line MLG corresponding to the main power-source voltage line MLVDM and the source power-source voltage line MLVDP described above, and a branch reference power-source voltage line MLGB corresponding to the branch power-source voltage line MLVB.

Similarly, in the even metal line layer, the comb-tooth-shaped power-source voltage line and the power-source voltage line for interconnection connection inside the above-described even metal line layers are folded back symmetrically to the Y-axis, and the comb-tooth-shaped reference power-source voltage line for interlayer connection are disposed such that the XY coordinates of the teeth are shifted by a predetermined pitch in the Y-axis direction. As in the case of the above-described contact layers CTvd1 and CTvd2, the reference power-source voltage lines are appropriately connected through contact layers CTvs1 and CTvs2, whose connection positions are different in the odd or even metal line layers. As in this example, by appropriately performing the buckling deformation on the contact layer (or via), the on-chip capacitor CCb can be achieved as illustrated in FIGS. 17A and 17B.

By using the semiconductor device of the present fourth embodiment, it is possible to achieve the on-chip capacitor efficiently operating as the bypass capacitor, in addition to the effect described in the first embodiment. That is, the electrode of the on-chip capacitor can be formed by the metal line having a low resistance. Also, by using the inter-metal-line insulating film ISLm inside the same metal line layer and the interlayer insulating film ISLy between different metal line layers, a capacitance value that is large to some extent can be obtained. Furthermore, since the on-chip capacitor is configured by the unit cell, the on-chip capacitor can be efficiently disposed around the core circuit block CRBK by the so-called self-aligned line.

### Fifth Embodiment

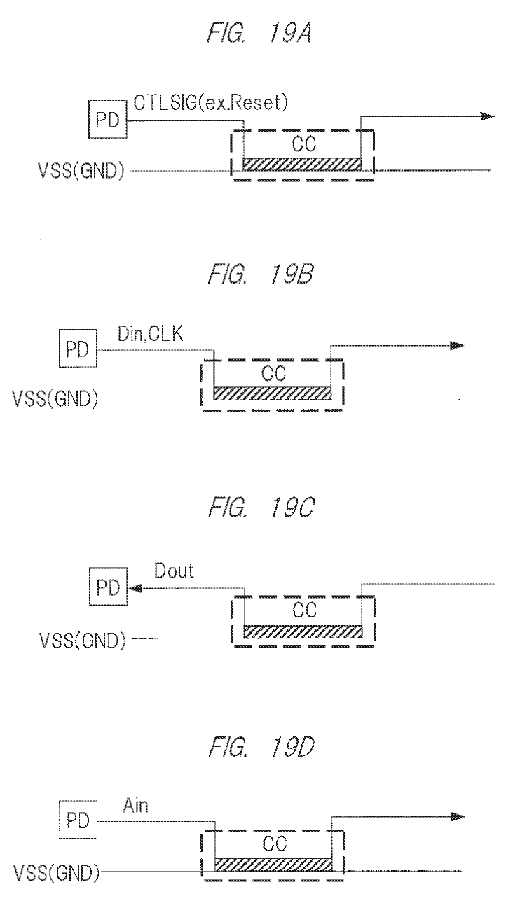

In the present fifth embodiment, an example in which the above-described on-chip capacitor CC is applied to places other than the power source voltage and reference power source voltage will be described. FIGS. 19A to 19D are schematic diagrams illustrating different configuration examples of a main part in a semiconductor device according to the fifth embodiment of the present invention. FIG. 19A illustrates an example in which the on-chip capacitor CC described above with reference to FIG. 6 or the like is applied to a control signal CTLSIG such as a reset signal or the like. Similarly, FIG. 19B illustrates an example in which the CC is applied to an input data signal Din or a clock signal CLK. FIG. 19C illustrates an example in which the CC is applied to an output data signal Dout. FIG. 19D illustrates an example in which the CC is applied to an analog input signal Ain.

Although not specifically limited thereto, the on-chip capacitor CC is disposed adjacent to a pad PD of each signal. In any case, the on-chip capacitor CC is used to bypass noise components having a frequency band much higher than a frequency band of each signal. Therefore, for example, it is possible to reduce EMI noise (emission noise) generated in the PD or to reduce noise components included in the signals input from the PD.

In the foregoing, the invention made by the inventors of the present invention has been concretely described based on the embodiments. However, it is needless to say that the present invention is not limited to the foregoing embodiments and various modifications and alterations can be made within the scope of the present invention. For example, the embodiments described above have been described in detail for facilitating understanding of the invention and thus they are not necessarily limited to those having all of the components described above. In addition, a part of a configuration of one embodiment can be replaced with another configuration of another embodiment and also another configuration of another embodiment can be added to one configuration of one embodiment. Moreover, as to a part of a configuration of each of the embodiments, another configuration can be added to it, eliminated from it, or replaced with it.

For example, herein, the microcomputer has been exemplarily described as the semiconductor device, but it is obvious that the semiconductor device is not limited to the microcomputer and can be equally applied to various semiconductor products that require noise countermeasures. Also, the on-chip capacitor CCa illustrated in FIG. 11B or the on-chip capacitor CCb illustrated in FIGS. 17A and 17B can be achieved as discrete capacitor parts according to circumstances.

### EXPLANATION OF REFERENCE NUMERALS

AMP Amplifier circuit
ANGBK Analog circuit block
Ain Analog input signal
BD Wiring board
BGR Bandgap reference circuit
CC, CC′ On-chip capacitor
CE External capacitor
CHP Semiconductor chip
CKBK Clock generating circuit block
CL Cell
CP Parasitic Capacitance
CPU Processor circuit
CRBK Core circuit block
CS Current source
CT Contact layer
CTLSIG Control signal
DF Diffusion layer
G Layer
GL Gate line
GOX Gate insulating film
GT Gate layer
IC Semiconductor package
IOBK External input/output block (IO block)
IS Insulating film
ISL Insulating film
LNVD Power-source voltage line
LNVS Reference power-source voltage line
LWN Lower electrode
M Metal line layer
MGL Metal gate line
ML Metal line
MLG Reference power-source voltage line
MLGB Branch reference power-source voltage line
MLVC External power-source voltage line
MLVB Branch power-source voltage line
MLVDM Main power-source voltage line
MLVDS Sub power-source voltage line
MP PMOS transistor
N Node
Nvdd Power-source source node
PD Pad
PERI Various peripheral circuits
PN External terminal
PSL Polysilicon layer
RAM Volatile memory
ROM Nonvolatile memory
RV Variable resistor
SC Silicide layer
STI Element-separation insulating film
UPN Upper electrode
VCC Power source voltage
VDD Internal power source voltage
VREFG Reference voltage generating circuit
VREG Power-source voltage regulator circuit
VSS Reference power source voltage
Vref Reference voltage
WEL Well

What is claimed is:

1. A semiconductor device formed of a single semiconductor substrate, comprising:
a first region for forming a core circuit block executing a predetermined process;
a first power-source voltage line disposed in the first region, the first power-source voltage line for supplying a power source voltage to the core circuit block;
a power-source source node disposed on the outside of the first region, the power-source source node for serving as a supply source of the power source voltage;
a second power-source voltage line for connecting the power-source source node and the first power-source voltage line; and
an on-chip capacitor including a first electrode being a partial section of the second power-source voltage line and a second electrode for supplying a reference power source voltage, the on-chip capacitor being configured by a unit cell,
wherein the power source voltage from the power-source source node is supplied to the core circuit block through the first electrode.

2. The semiconductor device according to claim 1,
wherein the on-chip capacitor functions as a bypass capacitor of the core circuit block.

3. The semiconductor device according to claim 2,
wherein the first power-source voltage line includes:
a main power-source voltage line disposed along an outer peripheral portion of the first region; and
a sub power-source voltage line branched from the main power-source voltage line and disposed in a mesh shape, and
wherein one end of the first electrode of the on-chip capacitor is connected to the main power-source voltage line, and the other end of the first electrode of the on-chip capacitor is connected to the power-source source node.

4. The semiconductor device according to claim 3,
wherein the supply of the power source voltage from the power-source source node to the core circuit block is all performed through the first electrode.

5. The semiconductor device according to claim 4,
wherein a plurality of on-chip capacitors are disposed along the main power-source voltage line.

6. The semiconductor device according to claim 5, further comprising a power regulator circuit for generating the power source voltage to the power-source source node,
wherein the power regulator circuit is disposed between the plurality of on-chip capacitors.

7. The semiconductor device according to claim 5,
wherein the power-source source node is an external terminal.

8. The semiconductor device according to claim 2,
wherein the on-chip capacitor includes:
a well formed in the semiconductor substrate and serving as the second electrode;
an insulating film formed on the well; and
a gate line formed on the insulating film and serving as the first electrode.

9. The semiconductor device according to claim 2,
wherein the on-chip capacitor is formed by using a plurality of metal line layers on the semiconductor substrate, an inter-metal-line insulating film dividing the respective metal lines in the same metal line layer, and an interlayer insulating film separating different metal line layers.

10. A semiconductor device configured in a single semiconductor substrate, comprising:
a first region for forming a core circuit block for executing a predetermined process;
a first power-source voltage line disposed in the first region, the first power-source voltage line for supplying a power source voltage to the core circuit block;
a power-source source node disposed on the outside of the first region, the power-source source node serving as a supply source of the power source voltage;
a second power-source voltage line for connecting the power-source source node and the first power-source voltage line; and
an on-chip capacitor having a first electrode being a partial section of the second power-source voltage line, and a second electrode to which a reference power source voltage is supplied, the on-chip capacitor being configured by a unit cell,
wherein the on-chip capacitor includes:
a well of a first conductivity type formed in the semiconductor substrate;
a first semiconductor region of the first conductivity type formed in the well and having a higher impurity concentration than the well;
an insulating film formed on the well;
a gate line formed on the insulating film; and
first and second contact layers, each of which is formed on both ends of the gate line,
wherein the gate line serves as the first electrode, and
wherein the well serves as the second electrode by supplying the reference power source voltage to the first semiconductor region.

11. The semiconductor device according to claim 10,
wherein the gate line is formed of a metal gate.

12. The semiconductor device according to claim 11,
wherein the first power-source voltage line includes:
a main power-source voltage line disposed along an outer peripheral portion of the first region; and
a sub power-source voltage line branched from the main power-source voltage line and disposed in a mesh shape,
the first contact layer is connected to the main power-source voltage line, and
the second contact layer is connected to the power-source source node.

13. The semiconductor device according to claim 12,
wherein the supply of the power source voltage from the power-source source node to the core circuit block is all performed through the gate line.

14. The semiconductor device according to claim 13,
wherein a plurality of on-chip capacitors are disposed along the main power-source voltage line.

15. The semiconductor device according to claim 14, wherein the first conductivity type is an n-type.

16. A semiconductor device configured in a single semiconductor substrate, comprising:
a first region for forming a core circuit block for executing a predetermined process;
a first power-source voltage line disposed in the first region to supply a power source voltage to the core circuit block;
a power-source source node disposed outside the first region to serve as a supply source of the power source voltage;
a second power-source voltage line disposed to connect the power-source source node and the first power-source voltage line; and
an on-chip capacitor having a first electrode being a partial section of the second power-source voltage line, and a second electrode to which a reference power source voltage is supplied, the on-chip capacitor being configured by a unit cell,
wherein the first and second electrodes are formed by a metal line layer on the semiconductor substrate,
the first electrode includes a plurality of first metal lines extending in parallel in a first direction between first and second nodes being both ends of a partial section of the second power-source voltage line, and
the second electrode includes a plurality of second metal lines extending in parallel in the first direction and disposed at a predetermined interval such that an insulating film is interposed with respect to the plurality of first metal lines.

17. The semiconductor device according to claim 16,
wherein the plurality of first and second metal lines are formed by multi-layered metal lines on the semiconductor substrate, and
when the plurality of first and second metal lines are viewed in a cross-section in a second direction that is perpendicular to the first direction, the first metal line and the second metal line are alternately disposed in the same layer of the multi-layered metal line layer and is alternately disposed in a layer direction of the multi-layered metal line layer.

18. The semiconductor device according to claim 17,
wherein the first power-source voltage line includes:
a main power-source voltage line disposed along an outer peripheral portion of the first region; and
a sub power-source voltage line branched from the main power-source voltage line and disposed in a mesh shape,
wherein the first node is connected to the main power-source voltage line, and
wherein the second node is connected to the power-source source node.

19. The semiconductor device according to claim 18,
wherein the supply of the power source voltage from the power-source source node to the core circuit block is all performed through the plurality of first metal lines.

20. The semiconductor device according to claim 19,
wherein a plurality of on-chip capacitors are disposed along the main power-source voltage line.
